(19) United States
(12) Patent Application Publication
(10) Pub. No.: US 2009/0246965 A1
(43) Pub. Date: Oct. 1, 2009

(54) ETCHING METHOD AND MANUFACTURING METHOD OF SEMICONDUCTOR DEVICE

(75) Inventors: Takuya Mori, New York, NY (US); Masahiko Takahashi, Hyogo (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/410,504

(22) Filed: Mar. 25, 2009

(30) Foreign Application Priority Data
Mar. 26, 2008 (JP) 2008-080875

(51) Int. Cl. H01L 21/3065

(52) U.S. Cl. 438/719; 257/E21.218

(57) ABSTRACT

Provided is an etching method capable of increasing a selectivity of a polysilicon film with respect to a silicon oxide film and suppressing the formation of recesses in a silicon base material. A wafer includes a gate oxide film, a polysilicon film and a hard mask film having an opening sequentially formed on a silicon base material, and has a native oxide film in a trench of the polysilicon film corresponding to the opening formed thereon. The native oxide film is etched, so that the polysilicon film is exposed at a bottom portion of the trench. An ambient pressure is set to be 13.3 Pa, and O₂ gas, HBr gas and Ar gas are supplied to a processing space, and a frequency of bias voltage is set to be 13.56 MHz, so that the polysilicon film is etched by the plasma generated from the HBr gas to be completely removed.

### FIELD OF THE INVENTION

The present disclosure relates to an etching method and a manufacturing method of a semiconductor device; and, more particularly, to an etching method of etching a polysilicon layer formed on a gate oxide film.

### BACKGROUND OF THE INVENTION

In case of forming a gate of polysilicon (polycrystalline silicon) single layer in a semiconductor device, processed is a wafer having a structure of a gate oxide film 101 made of silicon oxide, a polysilicon film 102 and a hard mask film (SiN film) 103 sequentially formed on a silicon base material 100. In this wafer, the hard mask film 103 is formed in a preset pattern and has an opening 104 at a predetermined position, and the polysilicon film 102 has a groove (trench) 105 corresponding to the opening 104. Further, formed in the trench 105 is a native oxide film 106 generated by natural oxidation of a part of exposed polysilicon film 102 (see FIG. 7A).

A process for processing the wafer includes a breakthrough etching step and a main etching step which are performed in one chamber serving as a substrate processing chamber, and an oxide film etching step performed in the other chamber serving as a substrate processing chamber. In the breakthrough etching step performed in the one chamber, the native oxide film 106 in the trench 105 is etched, so that the polysilicon film 102 is exposed at a bottom portion of the trench 105 (FIG. 7B). Furthermore, in the main etching step performed in the one chamber, the polysilicon film 102 at the bottom portion of the trench 105 is etched to be completely removed, so that the gate oxide film 101 is exposed (FIG. 7C). Thereafter, the wafer is transferred to the other chamber. Then, in the oxide film etching step performed in the other chamber, the gate oxide film 101 is etched to be removed, thereby exposing the silicon base material 100 (FIG. 7D). Further, ions are doped into the exposed silicon base material 100 later.

In general, used for etching the polysilicon film 102 is plasma generated from a hydrogen bromide (HBr)-based processing gas, which does not contain a chlorine-based gas or a fluorine-based gas (for example, see Patent Document 1).

However, there has been known that if an oxygen gas is mixed into the processing gas, a selectivity of the polysilicon film 102 with respect to the gate oxide film 101 can be greatly increased when performing the etching, so that the etching of the gate oxide film 101 can be suppressed (effect of securing the selectivity by mixing the oxygen gas). Therefore, generally, the oxygen gas is mixed into the processing gas such that the gate oxide film 101 is not etched in the main etching step.
Patent Document 1: Japanese Patent Laid-open Publication No. H10-172959

### BRIEF SUMMARY OF THE INVENTION

However, the gate oxide film 101 exposed at the bottom portion of the trench 105 is thin, so that if a maximum energy of positive ions in oxygen plasma generated from the oxygen gas is high in the main etching step, there is a likelihood that the positive ions pass through the gate oxide film 101 and reach the silicon base material 100 (FIG. 7C). The positive ions of oxygen reaching the silicon base material 100 modify a part 107 of the silicon base material 100 into silicon oxide. Further, in the oxide film etching step performed in the other chamber, plasma generated from a HF-based gas removes not only the gate oxide film 101 but also the modified part 107 of the silicon base material 100. As a result, formed at both sides of a gate are recesses 108, which are recessed from a surface of the silicon base material 100 (FIG. 7D).

If the recesses 108 are formed, ions are not doped into a desired area when doping ions into the exposed silicon base material 100. As a result, a desired performance of the semiconductor device can not be obtained.

The present disclosure provides an etching method and a manufacturing method of a semiconductor device, capable of increasing a selectivity of a polysilicon film with respect to a silicon oxide film and suppressing the formation of recesses in a silicon base material.

In accordance with one aspect of the present disclosure, there is provided an etching method of a substrate in which at least a silicon oxide film, a polysilicon film and a mask film having an opening are sequentially formed on a silicon base material, the method including: a polysilicon film etching process for etching the polysilicon film corresponding to the opening by using plasma generated from a processing gas containing an oxygen gas, wherein, in the polysilicon film etching process, an ambient pressure is set to be in a range from about 6.7 Pa to 33.3 Pa and a frequency of bias voltage for providing the plasma to the substrate is set to be equal to or more than about 13.56 MHz, so that the polysilicon film corresponding to the opening is etched.

In the etching method, during the polysilicon film etching process, the ambient pressure may be set to be in a range from about 13.3 Pa to 26.6 Pa.

In the etching method, the processing gas containing the oxygen gas may be a mixed gas of the oxygen gas, a hydrogen bromide gas and an inactive gas.

The etching method may further include: prior to the polysilicon film etching process, a native oxide film removing process for removing a native oxide film generated from the polysilicon film, wherein, in the native oxide film removing process, the native oxide film is etched by using plasma generated from a hydrogen bromide gas, a carbon fluoride gas or a chlorine gas.

The etching method may further include a silicon oxide film etching process for etching the silicon oxide film.

In accordance with another aspect of the present disclosure, there is provided a semiconductor device manufacturing method for manufacturing a semiconductor device with a substrate in which at least a silicon oxide film, a polysilicon film and a mask film having an opening are sequentially formed on a silicon base material, the method including: a polysilicon film etching process for etching the polysilicon film corresponding to the opening by using plasma generated from a processing gas containing an oxygen gas, wherein, in the polysilicon film etching process, an ambient pressure is set to be in a range from about 6.7 Pa to 33.3 Pa and a frequency of bias voltage for providing the plasma to the substrate is set to be equal to or more than about 13.56 MHz, so that the polysilicon film corresponding to the opening is etched.

In accordance with one embodiment of the etching method and the semiconductor device manufacturing method, the polysilicon film corresponding to the opening of the mask film is etched by using the plasma generated from the processing gas including the oxygen gas under an ambient pressure in a range from about 6.7 Pa to 33.3 Pa and a bias voltage frequency of about 13.56 MHz or more for introducing the plasma to the substrate. If the ambient pressure is equal to or more than about 6.7 Pa, the maximum energy of the positive ions in the plasma decreases. Further, if the bias voltage frequency is equal to or more than about 13.56 MHz, the positive ions in the plasma can not keep up with voltage variations of the bias voltage, so that the maximum energy of the positive ions in the plasma also decreases. Accordingly, a sputtering force of the plasma decreases, so that an etching rate of the silicon oxide film decreases considerably in comparison to an etching rate of the polysilicon film. Further, the selectivity securing effect by the mixture of the oxygen gas is also obtained. Accordingly, it is possible to increase the selectivity of the polysilicon film with respect to the silicon oxide film.

Moreover, as stated above, if the ambient pressure is equal to or more than about 6.7 Pa and the bias voltage frequency is equal to or more than about 13.56 MHz, the maximum energy of the positive ions in the plasma decreases, so that it is possible to prevent the positive ions from passing through the silicon oxide film and reaching the silicon base material, thereby preventing the silicon base material below the silicon oxide film from being oxidized. As a result, the formation of the recess can be suppressed.

In accordance with one embodiment of the etching method, the polysilicon film is etched under the ambient pressure in a range from about 13.3 Pa to 26.6 Pa. If the pressure is equal to or more than about 13.3 Pa, the maximum energy of the positive ions in the plasma decreases excessively and the sputtering force decreases excessively, so that the selectivity of the polysilicon film with respect to the silicon oxide film can be securely increased. As a result, it is possible to prevent the silicon oxide film from being damaged.

In accordance with one embodiment of the etching method, the processing gas containing the oxygen gas is a mixed gas of the oxygen gas, the hydrogen bromide gas and an inactive gas. The plasma generated from the hydrogen bromide gas can etch the polysilicon film effectively. Therefore, it is possible to improve the throughput.

In accordance with one embodiment of the etching method, in the native oxide film removing process, the native oxide film is etched by using plasma generated from the hydrogen bromide gas, the carbon fluoride gas or the chlorine gas. The plasma generated from the hydrogen bromide gas, the carbon fluoride gas or the chlorine gas can etch the native oxide film effectively. Therefore, it is possible to further improve the throughput.

In accordance with one embodiment of the etching method, the silicon oxide film is etched, so that the silicon base material, which will be ion-doped, can be securely exposed.

### BRIEF DESCRIPTION OF THE DRAWINGS

The disclosure may best be understood by reference to the following description taken in conjunction with the following figures:

FIG. 1 is a cross sectional view showing an overview structure of a substrate processing apparatus for performing an etching method in accordance with an embodiment of the present disclosure;

FIG. 2 is a plane view of a slot plate of FIG. 1;

FIG. 3 is a plane view of a processing gas supply unit of FIG. 1 when viewed from the bottom;

FIG. 4 is a cross sectional view illustrating a structure of a wafer on which an etching process is performed in the substrate processing apparatus of FIG. 1;

FIGS. 5A to 5D are process diagrams illustrating an etching method for obtaining a gate structure of a semiconductor device as the etching method in accordance with the present embodiment;

FIGS. 6A and 6B are cross sectional views illustrating a gate structure in a wafer obtained by the etching; FIG. 6A shows a gate structure obtained when a pressure of a processing space is set to be about 13.3 Pa and a bias voltage frequency is set to be about 13.56 MHz during the etching of a remaining polysilicon film; and FIG. 6B shows a gate structure obtained when a pressure of a processing space is set to be about 13.3 Pa and a bias voltage frequency is set to be about 400 kHz during the etching of the remaining polysilicon film; and

FIGS. 7A to 7D are process diagrams illustrating a conventional etching method for obtaining a gate structure.

### EXPLANATION OF CODES

G1: Processing gas

S1, S2: Processing spaces

W: Wafer

10: Substrate processing apparatus

11: Processing chamber

12: Susceptor

13: Microwave transmissive window

14: Ring member

19: Radial line slot antenna

20: Slot plate

21: Antenna dielectric plate

22: Wavelength shortening plate

24: Coaxial waveguide

25a, 25b: Slots

28: Processing gas supply unit

33: High frequency power supply

35: Silicon base material

36: Gate oxide film

37: Polysilicon film

39: Opening

40: Trench

41: Native oxide film

### DETAILED DESCRIPTION OF THE INVENTION

Hereinafter, embodiments of the present disclosure will be explained with reference to the accompanying drawings.

First, there will be explained a substrate processing apparatus for performing an etching method in accordance with an embodiment of the present disclosure.

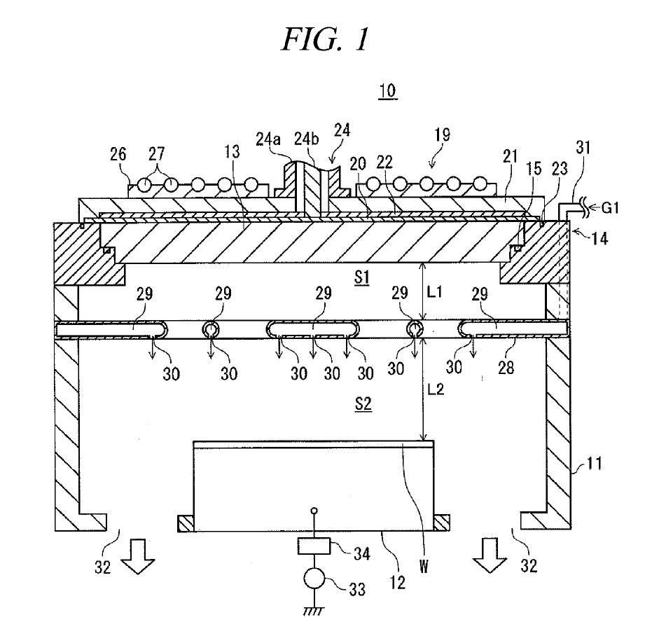

FIG. 1 is a cross sectional view showing an overview structure of a substrate processing apparatus for performing an etching method in accordance with the present embodiment.

In FIG. 1, a substrate processing apparatus 10 includes a substantially cylindrical processing chamber 11 and a substantially cylindrical susceptor 12, which is installed in the processing chamber 11 and serves as a mounting table for mounting thereon a wafer W to be described later. The susceptor 12 has an electrostatic chuck (not illustrated). The electrostatic chuck attracts and holds the wafer W by Coulomb force or Johnson-Rahbek force.

The processing chamber 11 is made of, for example, austenite stainless steel containing aluminum, and an inner wall surface thereof is covered with an insulating film (not illustrated) made of alumite or yttria (Y₂O₃). Further, in a top portion of the processing chamber 11, installed is a microwave transmissive window 13 made of a dielectric plate, e.g., a quartz plate through a ring member 14 so as to face the wafer W attracted and held onto the susceptor 12. The microwave transmissive window 13 has a circular plate shape and allows a microwave to be described later to pass therethrough.

A stepped portion is formed at an outer peripheral portion of the microwave transmissive window 13, and a stepped portion corresponding to the stepped portion of the microwave transmissive window 13 is formed at an inner peripheral portion of the ring member 14. The microwave transmissive window 13 and the ring member 14 are coupled to each other by engaging the stepped portions thereof. A seal ring 15, which is an O-ring, is installed between the stepped portion of the microwave transmissive window 13 and the stepped portion of the ring member 14, and the seal ring 15 prevents a gas leakage from the microwave transmissive window 13 and the ring member 14, so that the inside of the processing chamber 11 is airtightly maintained.

A radial line slot antenna 19 is disposed on the microwave transmissive window 13. The radial line slot antenna 19 includes a circular plate-shaped slot plate 20 making a close contact with the microwave transmissive window 13, a circular plate-shaped antenna dielectric plate 21 holding and covering the slot plate 20, and a wavelength shortening plate 22 interposed between the slot plate 20 and the antenna dielectric plate 21. The wavelength shortening plate 22 is made of low-loss dielectric material of Al₂O₃, SiO₂ and Si₃N₄.

The radial line slot antenna 19 is mounted on the processing chamber 11 through the ring member 14. A seal ring 23, which is an O-ring, is interposed between the radial line slot antenna 19 and the ring member 14 so as to hermetically seal them. Further, a coaxial waveguide 24 is connected to the radial line slot antenna 19. The coaxial waveguide 24 includes a pipe 24a and a rod-shaped central conductor 24b disposed coaxially with the pipe 24a. The pipe 24a is connected to the antenna dielectric plate 21, and the central conductor 24b is connected to the slot plate 20 through an opening formed in the antenna dielectric plate 21.

Furthermore, the coaxial waveguide 24 is connected with an external microwave source (not illustrated) and supplies a microwave having a frequency of about 2.45 GHz or 8.3 GHz to the radial line slot antenna 19. The supplied microwave proceeds between the antenna dielectric plate 21 and the slot plate 20 in a diametric direction. The wavelength shortening plate 22 shortens a wavelength of the proceeding microwave.

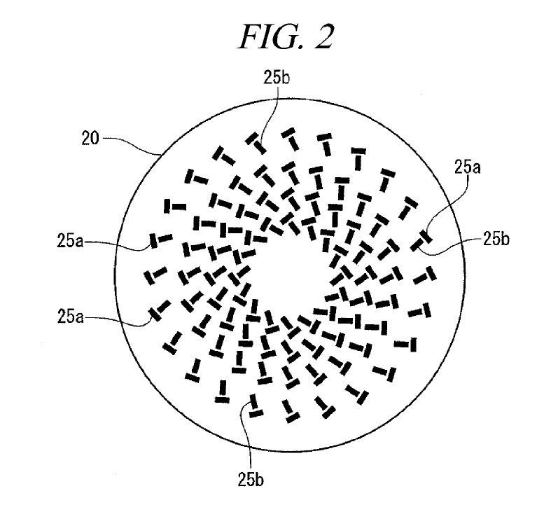

FIG. 2 shows a plane view of the slot plate of FIG. 1.

In FIG. 2, the slot plate 20 includes a plurality of slots 25a and slots 25b equal in number to the number of the slots 25a. The plurality of slots 25a is arranged in plural concentric circular shapes, and the respective slots 25b correspond to the respective slots 25a and they are arranged orthogonal to each other. In a slot group of a pair of the slot 25a and the corresponding slot 25b, a distance between the slot 25a and the slot 25b in a radial direction of the slot plate 20 corresponds to a wavelength of the microwave shortened by the wavelength shortening plate 22. Accordingly, the microwave is radiated as an approximately plane wave from the slot plate 20. Furthermore, since the slot 25a and the slot 25b are arranged orthogonal to each other, the microwave radiated from the slot plate 20 shows a circularly polarized wave including two polarized wave components orthogonal to each other.

Referring again to FIG. 1, the substrate processing apparatus 10 includes a cooling block body 26 on the antenna dielectric plate 21. The cooling block body 26 has a plurality of cooling water paths 27. The cooling block body 26 removes heat, which is accumulated in the microwave transmissive window 13 heated by the microwave, via the radial line slot antenna 19 by a heat exchange of coolant circulating through the cooling water paths 27.

Further, the substrate processing apparatus 10 includes a processing gas supply unit 28 disposed between the microwave transmissive window 13 and the susceptor 12 in the processing chamber 11. The processing gas supply unit 28 is made of a conductor such as a magnesium-containing aluminum alloy or an aluminum-containing stainless steel, and is disposed to face the wafer W mounted on the susceptor 12.

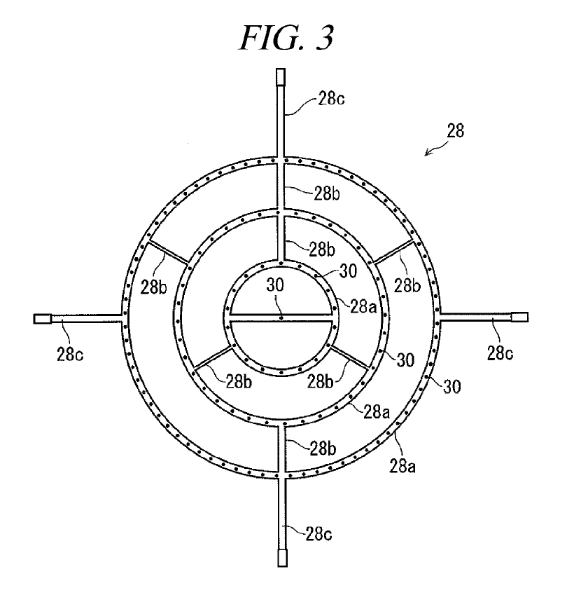

Furthermore, the processing gas supply unit 28 includes, as illustrated in FIG. 3, a plurality of circular pipes 28a disposed concentrically and having different diameters, a plurality of connection pipes 28b for connecting the respective circular pipes 28a together, and supporting pipes 28c for supporting the circular pipes 28a and the connection pipes 28b by connecting the outermost circular pipe 28a with a sidewall of the processing chamber 11.

All of the circular pipes 28a, the connection pipes 28b and the supporting pipes 28c are tube-shaped, and processing gas diffusion paths 29 are formed within these pipes. The processing gas diffusion paths 29 are communicated with a processing space S2 between the processing gas supply unit 28 and the susceptor 12 through a plurality of gas holes 30 formed at a bottom surface of the respective circular pipes 28a. Furthermore, the processing gas diffusion paths 29 are connected with an external processing gas supply unit (not illustrated) through a processing gas introduction pipe 31. The processing gas introduction pipe 31 introduces a processing gas G1 into the processing gas diffusion paths 29. Each of the gas holes 30 supplies the processing gas G1 introduced into the processing gas diffusion paths 29 to the processing space S2.

Further, the substrate processing apparatus 10 may not include the processing gas supply unit 28. In this case, the ring member 14 may include a gas hole so as to supply the processing gas to processing spaces S1 and S2.

Moreover, the substrate processing apparatus 10 includes a gas exhaust port 32 at a bottom portion of the processing chamber 11. The gas exhaust port 32 is connected to a TMP (Turbo Molecular Pump) or a DP (Dry Pump) (neither illustrated) through an APC (Automatic Pressure Control) valve (not illustrated). The TMP or the DP exhausts a gas within the processing chamber 11, and the APC valve controls a pressure within the processing spaces S1 and S2.

Furthermore, in the substrate processing apparatus 10, the susceptor 12 is connected with a high frequency power supply 33 through a matcher 34, and the high frequency power supply 33 supplies a high frequency power to the susceptor 12. Accordingly, the susceptor 12 functions as a high frequency electrode. Further, the matcher 34 reduces the reflection of the high frequency power from the susceptor 12, thereby maximizing the supply efficiency of the high frequency power to the susceptor 12. A high frequency current from the high frequency power supply 33 is supplied to the processing spaces S1 and S2 via the suscpetor 12 and generates a bias voltage for supplying plasma, which will be described later, to the wafer W attracted and held onto the susceptor 12.

Further, a distance L1 between the microwave transmissive window 13 and the processing gas supply unit 28 (i.e., a thickness of the processing space S1) is about 35 mm, and a distance L2 between the processing gas supply unit 28 and the susceptor 12 (i.e., a thickness of the processing space S2) is about 100 mm. In addition, the processing gas G1 supplied by the processing gas supply unit 28 may include a single gas or a mixed gas selected from a hydrogen bromide (HBr) gas, a carbon fluoride (CF-based) gas, a chlorine (Cl₂) gas, a hydrogen fluoride (HF) gas, an oxygen (O₂) gas, a hydrogen (H₂) gas, a nitrogen (N₂) gas and a rare gas such as an argon (Ar) gas or helium (He) gas.

In the substrate processing apparatus 10, the pressure within the processing spaces S1 and S2 is controlled to a desired pressure, and the processing gas G1 is supplied from the processing gas supply unit 28 to the processing space S2. Subsequently, the high frequency current is supplied to the processing spaces S1 and S2 through the susceptor 12, and the radial line slot antenna 19 radiates the microwave from the slot plate 20. The radiated microwave is radiated to the processing spaces S1 and S2 through the microwave transmissive window 13 and generates a microwave electric field. The microwave electric field excites the processing gas G1 supplied to the processing space S2 into plasma. In this case, the processing gas G1 is excited by the microwave having a high frequency, so that it is possible to obtain high density plasma. The plasma of the processing gas G1 is supplied to the wafer W attracted and held onto the susceptor 12 by the bias voltage caused by the high frequency power supplied to the susceptor 12, and then an etching process is performed on the wafer W.

In the radial line slot antenna 19, the microwave supplied from the external microwave source is uniformly diffused between the antenna dielectric plate 21 and the slot plate 20, so that slot plate 20 radiates the microwave from its surface in a uniform manner. Accordingly, in the processing space S2, a uniform microwave electric field is generated and the plasma is uniformly distributed. As a result, the etching process can be performed on a surface of the wafer W in a uniform manner, so that it is possible to obtain the uniformity of process.

In the substrate processing apparatus 10, the processing gas G1 is excited into the plasma in the proximity of the processing gas supply unit 28 distanced away from the susceptor 12. That is, since the plasma is generated only in a space distanced away from the wafer W, the wafer W is not directly exposed to the plasma. Further, when the plasma reaches the wafer W, an electron temperature of the plasma is lowered. As a result, the semiconductor device structure on the wafer W is prevented from being damaged. Further, since the redissociation of the processing gas G1 can be prevented in the proximity of the wafer W, the contamination of the wafer W can be prevented (for example, “Yamanaka, Atoda, Won the Industry-Academic-Government Cooperation Contributor Awarding Prime Minister Award with ┌Development of Large Aperture and High Density Plasma Processing Apparatus┘”, Jun. 9, 2003, New Energy and Industry Technology Development Organization).

In the substrate processing apparatus 10, since the high frequency microwave is used for exciting the processing gas G1, it is possible to efficiently transfer energy to the processing gas G1. As a result, it becomes easy to excite the processing gas G1 and it is possible to generate the plasma even under a high pressure condition. Accordingly, it is possible to perform the etching process on the wafer W without excessively lowering the pressure of the processing spaces S1 and S2.

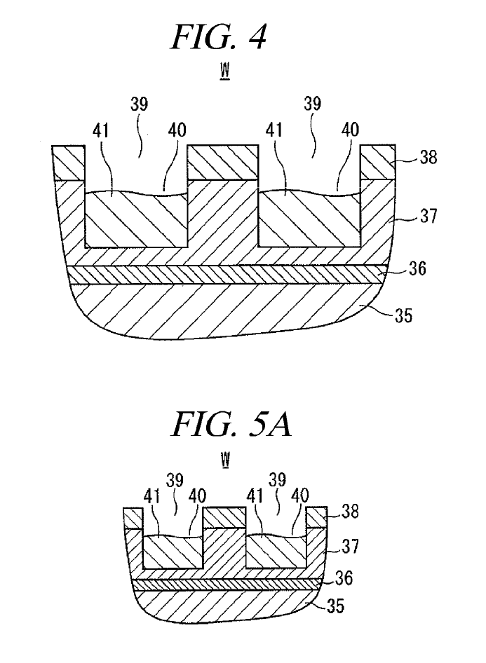

FIG. 4 is a cross sectional view illustrating a structure of a wafer on which an etching process is performed in the substrate processing apparatus of FIG. 1.

As illustrated in FIG. 4, a wafer W for a semiconductor device includes: a silicon base material 35 made of silicon; a gate oxide film 36 having a thickness of about 2.0 nm and formed on the silicon base material 35; a polysilicon film 37 having a thickness of about 100 nm and formed on the gate oxide film 36; and a hard mask film 38 formed on the polysilicon film 37. In the wafer W, the hard mask film 38 is formed in a predetermined pattern to have an opening 39 at a predetermined position, and the polysilicon film 37 has a groove (trench) 40 corresponding to the opening 39. Further, a native oxide film 41 is formed in the trench 40.

The silicon base material 35 is a thin film having a circular plate shape and made of silicon, and the gate oxide film 36 is formed on its surface by performing a thermal oxidation process. The gate oxide film 36 is made of silicon oxide (SiO₂) and functions as an insulating film. The polysilicon film 37 is made of polycrystalline silicon and is formed by a film forming process. Further, there is nothing doped in the polysilicon film 37.

The hard mask film 38 is made of silicon nitride (SiN). After forming a silicon nitride film to cover the entire surface of the polysilicon film 37 by a CVD process or the like, the silicon nitride film is etched by using a mask film, so that the opening 39 is formed at a predetermined position. Further, the trench 40 of the polysilicon film 37 is formed by performing an etching process using the hard mask film 38. The native oxide film 41 in the trench 40 is formed by a natural oxidation in which the polysilicon film 37 exposed by the etching process using the hard mask film 38 reacts with oxygen in the atmosphere.

Hereinafter, there will be explained an etching method in accordance with the present embodiment.

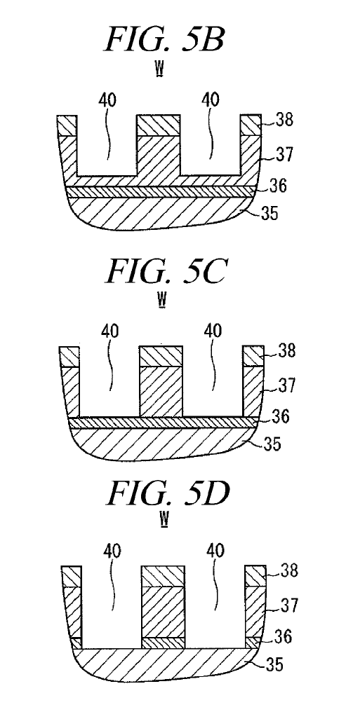

FIGS. 5A to 5D provide process diagrams illustrating an etching method for obtaining a gate structure of a semiconductor device as the etching method in accordance with the present embodiment.

In FIGS. 5A to 5D, first, the wafer W is loaded into the processing chamber 11 of the substrate processing apparatus 10 and is attracted and held onto the top surface of the susceptor 12 (FIG. 5A).

Subsequently, a pressure of the processing spaces S1 and S2 is set to be about 2.6 Pa (20 mTorr), and a Cl₂ gas and an Ar gas serving as the processing gas G1 are supplied from the processing gas supply unit 28 to the processing space S2 at respective preset flow rates. Furthermore, a microwave of about 2.45 GHz is supplied to the radial line slot antenna 19, and a power having high frequency of about 13.56 MHz is supplied to the susceptor 12. At this time, the Cl₂ gas or the like is excited into plasma by the microwave radiated from the slot plate 20, so that positive ions or radicals are generated. The positive ions or the radicals collide and react with the native oxide film 41 in the trench 40 through the opening 39, and the native oxide film 41 is etched, so that the polysilicon film 37 is exposed at the bottom portion of the trench 40 (native oxide film removing step) (FIG. 5B) (breakthrough etching).

Thereafter, a pressure of the processing spaces S1 and S2 is set to be about 13.3 Pa (100 mTorr), and an O₂ gas, a HBr gas and an Ar gas serving as the processing gas G1 are supplied to the processing space S2 at respective predetermined flow rates. Furthermore, a microwave of about 2.45 GHz is supplied to the radial line slot antenna 19, and a 13.56 MHz high frequency power of about 90 W is supplied to the susceptor 12. At this time, the HBr gas or the like is excited into plasma by the microwave radiated from the slot plate 20, so that positive ions or radicals are generated. The positive ions or the radicals collide and react with the polysilicon film 37, which is exposed at the bottom portion of the trench 40 and remains on the gate oxide film 36 (hereinafter, referred to as “remaining polysilicon film”), and the remaining polysilicon film is etched to be completely removed (polysilicon film etching step) (FIG. 5C) (main etching). Furthermore, the etching of the remaining polysilicon film is performed for, e.g., about 30 seconds.

When etching the remaining polysilicon film, the ambient pressure is set to be as high as about 13.3 Pa. Further, since the frequency of the high frequency power supplied to the susceptor 12 is set to be about 13.56 MHz, a frequency of the bias voltage derived by the high frequency power is also set to be about 13.56 MHz. If the ambient pressure is high, the maximum energy of the positive ions in the plasma decreases. Moreover, if the bias voltage frequency is equal to or more than about 13.56 MHz, the positive ions in the plasma can not keep up with voltage variations of the bias voltage, so that the maximum energy of the positive ions in the plasma also decreases. Accordingly, a sputtering force of the plasma decreases. Further, since silicon oxide is harder to be sputtered in comparison to polysilicon, if the sputtering force of the plasma decreases, an etching speed (hereinafter, referred to as “etching rate”) of the polysilicon decreases slightly, whereas an etching rate of the silicon oxide decreases considerably. As a result, it is possible to increase a selectivity of the polysilicon film 37 with respect to the gate oxide film 36.

Furthermore, as stated above, if the ambient pressure is high and the bias voltage frequency is equal to or more than about 13.56 MHz, the maximum energy of the positive ions in the plasma decreases, so that it is possible to prevent the positive ions from passing through the gate oxide film 36 and reaching the silicon base material 35, thereby preventing a part of the silicon base material 35 below the gate oxide film 36 from being oxidized.

Subsequently, the wafer W is unloaded from the processing chamber 11 of the substrate processing apparatus 10, and then loaded into a processing chamber of a wet etching apparatus (not illustrated). Then, a part of the gate oxide film 36 exposed by removing the polysilicon film 37 is wet etched by a liquid chemical or the like (silicon oxide film etching step). The part of the gate oxide film 36 is etched, so that the silicon base material 35 is exposed (FIG. 5D). Thereafter, the present process is finished.

According to the etching method in accordance with the present embodiment, the native oxide film 41 in the trench 40 is etched so as to expose the remaining polysilicon film at the bottom portion of the trench 40. Then, the remaining polysilicon film is etched by using the plasma generated from the processing gas G1 including the O₂ gas, the HBr gas and the Ar gas under the ambient pressure as high as about 13.3 Pa and the bias voltage frequency of about 13.56 MHz. If the ambient pressure is high and the bias voltage frequency is equal to or more than about 13.56 MHz, the sputtering force of the plasma decreases, so that the etching rate of the gate oxide film 36, which is difficult to be sputtered, decreases considerably. Further, since the processing gas G1 contains the O₂ gas, the selectivity securing effect by the mixture of the O₂ gas is obtained. Accordingly, it is possible to increase the selectivity of the polysilicon film 37 with respect to the gate oxide film 36.

Furthermore, as stated above, if the ambient pressure is high and the bias voltage frequency is equal to or more than about 13.56 MHz, the maximum energy of the positive ions in the plasma decreases, so that the positive ions do not pass through the gate oxide film 36 and a part of the silicon base material 35 below the gate oxide film 36 is not oxidized. As a result, when etching the gate oxide film 36, the part of the silicon base material 35 is not removed, so that the formation of a recess can be suppressed.

In the etching method in accordance with the present embodiment described above, when etching the native oxide film 41, the plasma generated from the Cl₂ gas is used. The plasma generated from the Cl₂ gas can effectively etch the native oxide film 41. Furthermore, when etching the remaining polysilicon film, the processing gas G1 including the O₂ gas, the HBr gas and the Ar gas is used. The plasma generated from the HBr gas can effectively etch the polysilicon film 37. Accordingly, the throughput can be improved.

Moreover, in the etching method in accordance with the present embodiment described above, the etching of the remaining polysilicon film is performed for 30 seconds, but an etching time is not limited thereto. In consideration of the throughput and the suppression of the etching of the gate oxide film 36, it is desirable that the etching time is short, particularly, in a range of from about 10 to 180 seconds.

Furthermore, in the etching method in accordance with the present embodiment described above, when etching the remaining polysilicon film, magnitude of the high frequency power supplied to the susceptor 12 is about 90 W, but the magnitude of the supplied high frequency power is not limited thereto, and it can be set according to the pressure of the processing spaces S1 and S2. The lower the pressure of the processing spaces S1 and S2, the stronger the sputtering force of the plasma becomes. Meanwhile, the smaller the magnitude of the supplied high frequency power, the weaker the sputtering force becomes. Accordingly, in order to suppress the etching of the gate oxide film 36, it is desirable to reduce the magnitude of the supplied high frequency power if the pressure of the processing spaces S1 and S2 decreases. To be specific, if the pressure of the processing spaces S1 and S2 is about 6.7 Pa (50 mTorr), it is desirable that the magnitude of the supplied high frequency power is about 45 W.

In addition, in the etching method in accordance with the present embodiment described above, when etching the remaining polysilicon film, the pressure of the processing spaces S1 and S2 (ambient pressure) is set to be about 13.3 Pa. However, in order to suppress the oxidization of a part of the silicon base material 35, it is possible to sufficiently reduce the maximum energy of the positive ions if the pressure of the processing spaces S1 and S2 is set to be equal to or more than about 6.7 Pa. Accordingly, it is possible to suppress the positive ions from passing through the gate oxide film 36. Furthermore, if the pressure of the processing spaces S1 and S2 is raised, the sputtering force of the plasma is decreased, and thus the throughput is decreased. Therefore, in order to suppress the decrease of the throughput, it is desirable to set the pressure of the processing spaces S1 and S2 to be equal to or less than about 33.3 Pa (250 mTorr), more desirably, equal to or less than about 26.6 Pa (200 mTorr).

Further, in the etching method in accordance with the present embodiment described above, when etching the remaining polysilicon film, the processing gas G1 including the O₂ gas, the HBr gas and the Ar gas is used, but the processing gas G1 is not limited thereto, and it may be also a processing gas containing only the HBr gas, and other inactive gases such as a rare gas (He gas) may be also used instead of the Ar gas.

In the etching method in accordance with the present embodiment described above, when etching the native oxide film 41, the mixed gas of the Cl₂ gas and the inactive gas is used as the processing gas G1, but the processing gas is not limited thereto. The HBr gas or the CF-based gas may be also used instead of the Cl₂ gas.

In the etching method in accordance with the present embodiment described above, the gate oxide film 36 is etched in the processing chamber of the wet etching apparatus, but it may be also possible to etch the gate oxide film 36 in the processing chamber 11 of the substrate processing apparatus 10.

Moreover, in the etching method in accordance with the present embodiment described above, when etching the remaining polysilicon film, the power having high frequency of about 13.56 MHz is supplied to the susceptor 12, but it may be also possible to supply a high frequency power having a higher frequency, to be specific, a high frequency power of about 27.13 MHz. As stated above, since the positive ions in the plasma can not keep up with the variations of the high frequency voltage, if the high frequency power having a high frequency is supplied by the susceptor 12, the maximum energy of the positive ions in the plasma is further decreased, whereby it is possible to further decrease the sputtering force of the plasma.

Further, an object of the present disclosure can also be achieved by providing a storage medium storing therein a program code of software implementing the functions of the embodiments to a system or an apparatus, and reading and executing the program code stored in the storage medium by a computer (or a CPU, a MPU or the like) of the system or the apparatus.

In this case, the program code itself read from the storage medium executes the functions of the embodiments described above, and the present disclosure is embodied by the program code and the storage medium storing therein the program code.

Further, as the storage medium for providing the program code, it may be possible to use, e.g., a floppy (registered trademark) disc, a hard disc, a magneto-optical disc, an optical disc such as a CD-ROM, a CD-R, a CD-RW, a DVD-ROM, a DVD-RAM, a DVD-RW or DVD+RW, a magnetic tape, a nonvolatile memory card, a ROM or the like. Otherwise, it may be possible to download the program code through a network.

Furthermore, the present disclosure includes a case in which the functions of the embodiments described above may be implemented by executing the program code read by the computer as well as a case in which an OS (Operating System) or the like operated on the computer executes a part or all of actual processes based on instructions of the program code so that the functions of the embodiments described above are implemented by these processes.

Moreover, the present disclosure also includes a case in which the program code read from the storage medium is written in a memory provided in a function extension board inserted into the computer or in a function extension unit connected to the computer, and then a CPU or the like, which has the extension function in the extension board or the extension unit, executes a part or all of actual processes based on instructions of the program code, so that the functions of the embodiments described above is implemented by these processes.

### EXPERIMENT EXAMPLE

Hereinafter, an experiment example of the present disclosure will be explained in detail.

Here, there has been examined an effect of a bias voltage frequency on the formation of a recess.

### EXPERIMENT EXAMPLE

First, the wafer W in FIG. 4 was prepared, and then the wafer W was loaded into the processing chamber 11 of the substrate processing apparatus 10. Further, the Cl₂ gas and the Ar gas serving as the processing gas G1 were supplied to the processing space S2, and the pressure of the processing spaces S1 and S2 was set to be about 2.5 Pa, and the microwave of about 2.45 GHz was supplied to the radial line slot antenna 19. In addition, the power having high frequency of about 13.56 MHz was supplied to the susceptor 12, and the native oxide film 41 was etched so that the polysilicon film 37 was exposed at the bottom portion of the trench 40. Furthermore, the O₂ gas, the HBr gas and the Ar gas serving as the processing gas G1 were supplied to the processing space S2, and the pressure of the processing spaces S1 and S2 was set to be about 13.3 Pa, and the remaining polysilicon film was etched by using the plasma generated from the HBr gas or the like. At this time, it has been found that the remaining polysilicon film was completely removed whereas the gate oxide film 36 was hardly etched.

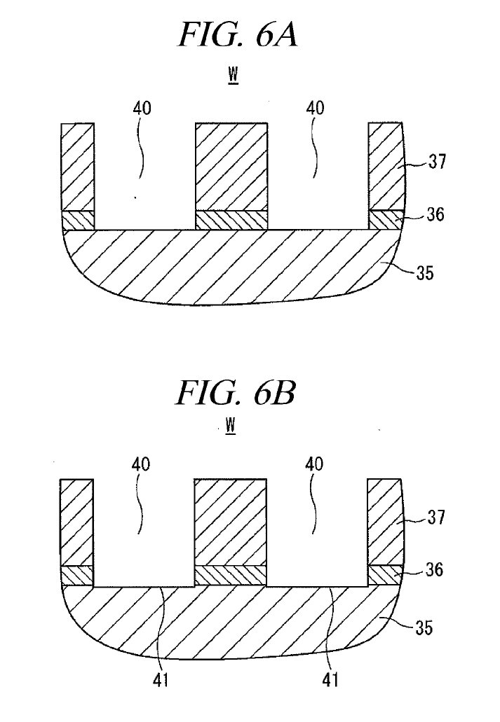

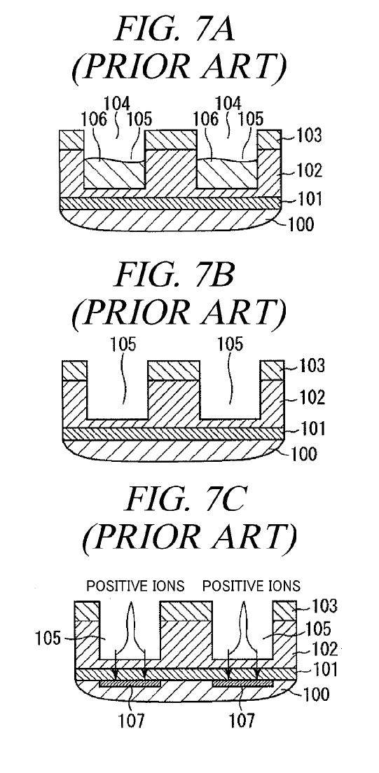

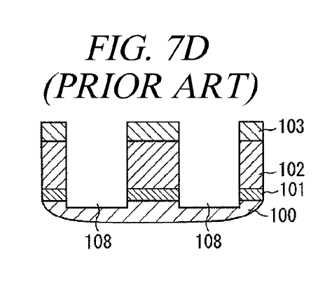

Then, the wafer W was loaded into the processing chamber of the wet etching apparatus, and the gate oxide film 36 exposed by completely removing the remaining polysilicon film was etched. Thereafter, in examining a gate of the wafer W, there has been found that a recess was hardly formed in the silicon base material 35 (see FIG. 6A).

The reasons why it was hard to completely prevent the formation of the recess in the silicon base material 35 have been deemed to be as follows. Because the O₂ gas is released from components of the processing chamber 11, which contains oxides, and reaches the silicon base material 35 during the etching of the remaining polysilicon film; some of the positive ions in the plasma generated from the O₂ gas in the processing gas G1 pass through the gate oxide film 36; and oxygen atom in the gate oxide film 36 reaches the silicon base material 35 serving as an underlayer by a knock-on phenomenon.

### COMPARATIVE EXAMPLE

First, under the same condition as the experiment example, the native oxide film 41 was etched so that the polysilicon film 37 is exposed at the bottom portion of the trench 40. Further, the O₂ gas, the HBr gas and the Ar gas serving as the processing gas G1 were supplied to the processing space S2, and the pressure of the processing spaces S1 and S2 is set to be about 13.3 Pa, and a high frequency power of about 400 kHz is supplied to the susceptor 12, and the remaining polysilicon film was etched by the plasma generated from the HBr gas or the like. Then, the exposed gate oxide film 36 was removed by completely removing the remaining polysilicon film. Thereafter, in examining a gate of the wafer W, there has been found that a recess 41 having a depth of 5.05 nm was formed in the silicon base material 35 (see FIG. 6B).

In view of the foregoing, when etching the remaining polysilicon film, the high frequency power having a relatively high frequency is supplied to the susceptor 12, so that the bias voltage frequency is set to be relatively high. To be specific, if it is set to be equal to or more than about 13.56 MHz, the maximum energy of the positive ions in the plasma decreases and the sputtering force decreases. Therefore, the etching rate of the gate oxide film 36 decreases, so that the selectivity of the polysilicon film 37 with respect to the gate oxide film 36 can be increased. Further, the positive ions in the plasma can be suppressed from passing through the silicon oxide film 36, so that the formation of the recess in the silicon base material 35 can be suppressed.

What is claimed is:

1. An etching method of a substrate in which at least a silicon oxide film, a polysilicon film and a mask film having an opening are sequentially formed on a silicon base material, the method comprising:
a polysilicon film etching process for etching the polysilicon film corresponding to the opening by using plasma generated from a processing gas containing an oxygen gas,
wherein, in the polysilicon film etching process, an ambient pressure is set to be in a range from about 6.7 Pa to 33.3 Pa and a frequency of bias voltage for providing the plasma to the substrate is set to be equal to or more than about 13.56 MHz, so that the polysilicon film corresponding to the opening is etched.

2. The etching method of claim 1, wherein, in the polysilicon film etching process, the processing gas in a processing chamber is excited into the plasma by a microwave introduced from a radial line slot antenna via a microwave transmissive window.

3. The etching method of claim 1, wherein, in the polysilicon film etching process, the ambient pressure is set to be in a range from about 13.3 Pa to 26.6 Pa.

4. The etching method of claim 1, wherein the processing gas containing the oxygen gas is a mixed gas of the oxygen gas, a hydrogen bromide gas and an inactive gas.

5. The etching method of claim 1, further comprising:
prior to the polysilicon film etching process, a native oxide film removing process for removing a native oxide film generated from the polysilicon film,
wherein, in the native oxide film removing process, the native oxide film is etched by using plasma generated from a hydrogen bromide gas, a carbon fluoride gas or a chlorine gas.

6. The etching method of claim 1, further comprising:
a silicon oxide film etching process for etching the silicon oxide film.

7. A semiconductor device manufacturing method for manufacturing a semiconductor device with a substrate in which at least a silicon oxide film, a polysilicon film and a mask film having an opening are sequentially formed on a silicon base material, the method comprising:
a polysilicon film etching process for etching the polysilicon film corresponding to the opening by using plasma generated from a processing gas containing an oxygen gas,
wherein, in the polysilicon film etching process, an ambient pressure is set to be in a range from about 6.7 Pa to 33.3 Pa and a frequency of bias voltage for providing the plasma to the substrate is set to be equal to or more than about 13.56 MHz, so that the polysilicon film corresponding to the opening is etched.

8. The semiconductor device manufacturing method of claim 7, wherein, in the polysilicon film etching process, the processing gas in a processing chamber is excited into the plasma by a microwave introduced from a radial line slot antenna via a microwave transmissive window.
